(19) United States
(12) Patent Application Publication
(10) Pub. No.: US 2011/0148457 A1
(43) Pub. Date: Jun. 23, 2011

(54) PROTECTING ELECTRONIC SYSTEMS FROM COUNTERFEITING AND REVERSE-ENGINEERING

(76) Inventor: Miron ABRAMOVICI, Berkeley Heights, NJ (US)

(21) Appl. No.: 12/903,952

(22) Filed: Oct. 13, 2010

Related U.S. Application Data
(60) Provisional application No. 61/251,251, filed on Oct. 13, 2009.

(51) Int. Cl. H03K 19/00; G06F 17/50

(52) U.S. Cl. 326/8; 716/100

(57) ABSTRACT

An exemplary embodiment provides an efficient solution for protecting electronic systems from counterfeiting and reverse-engineering. The exemplary embodiment may determine the operation of an electronic system by control logic. The control logic may be implemented by finite state machines (FSMs). The exemplary embodiment makes the behavior of the FSMs partially reconfigurable and hiding the configuration data in a secure memory device. With the configuration data stored in a secure memory device, the exemplary embodiment obfuscates the behavior of the FSMs both from the standpoint of the foundry as well as from adversaries.

### CROSS-REFERENCE TO RELATED APPLICATIONS

This application claims priority to provisional U.S. patent application No. 61/251,251 filed Oct. 13, 2009. The content of the aforementioned application is hereby incorporated herein by reference.

### BACKGROUND

This application relates to an electronic system that can be protected from counterfeiting and reverse-engineering. This application also relates to a method and an apparatus for designing an electronic system that can be protected from counterfeiting and reverse-engineering.

Electronic systems, which include hardware and/or software components, may be implemented on one or more monolithic devices that realize processing or control functions. The monolithic devices are referred to as “chips.” These chips may include processors, Programmable Logic Devices (PLDs), Integrated Circuits (ICs), Application Specific Integrated Circuits (ASICs), Application Specific Standard Products (ASSPs) and other off-the-shelf (OTS) components. Examples of the PLDs are Field Programmable Gate Array (FPGA), Complex Programmable Logic Device (CPLD), Programmable Array Logic (PAL), etc.

The chips may be designed in a design house and sent to silicon foundries for fabrication. The fabricated chips are assembled with other components and deployed to a target product. During these processes, individuals or organizations may have access to “soft” or “hard” intellectual property (IP) of the chips. The soft IP is represented by computer code, such as hardware description language, to describe abstract behavior or structure of the chips. This code is used to synthesize a real or hard IP of the chips. The individuals or organizations may include, but not limited to, chip foundries, integrated device manufacturers, contract manufacturers, parts distributors, and system integrators.

The protection of chip designs for critical applications is an essential security requirement. However, the security is difficult to achieve because a majority of System-on-Chip (SoC) fabrication occurs in silicon foundries where protection is not guaranteed. The layout masks used at the foundries may be reverse-engineered. Although the design is protected during fabrication, adversaries can obtain and reverse-engineer a fabricated chip. The production of counterfeit chips is a problem with significant implications, both in the commercial market and in the area of national security. Counterfeiting can be done easily through overproduction at the foundry (making additional copies of the device) or subsequently by using reverse-engineered masks.

One of the conventional protection solutions is a Physically Unclonable Function (PUF) technique. The PUF technique attaches an identifier depending on physical characteristics of the chip to provide an anti-counterfeiting capability. However, the identifier attached by the PUF technique is breakable with a moderate computational effort. Also, the identifiers attached by the PUF technique do not protect against reverse-engineering. Therefore, more efficient protection solution is needed to protect electronic systems from counterfeiting and reverse-engineering.

### BRIEF SUMMARY

An exemplary embodiment provides an efficient protection of electronic systems from counterfeiting and reverse-engineering. In the exemplary embodiment, an electronic system may include control logic and data-path logic implemented on a single chip. The exemplary embodiment may determine the operation of the electronic system by control logic. The control logic may be implemented by one or more finite state machines (FSMs) that direct communication protocols and the behavior of the data-path logic, such as registers, arithmetic logic units (ALUs), multipliers, etc. The exemplary embodiment protects the electronic system from counterfeiting and reverse-engineering by securing the FSM functionality of the control logic.

An exemplary embodiment makes the behavior of FSMs partially reconfigurable and hides configuration data in a secure memory device. The configuration data is loaded from the memory device and used to configure the FSMs when an electronic system is turned on. The original FSM configured with correct configuration data can be obfuscated by “fake” FSMs having incorrect configuration data. The exemplary embodiment obfuscates the behavior of the FSMs both from the standpoint of the foundry as well as from adversaries. A user may control the level of obfuscation.

In one aspect, a method is provided for designing an electronic system that can be protected from counterfeiting and reverse-engineering. The method includes describing the electronic system by one or more finite state machines (FSMs), and inserting a reconfigurable module in at least one of the FSMs. The reconfigurable module is configured by configuration data. The method also includes saving the configuration data separately from the reconfigurable module.

In another aspect, an electronic system is provided that is protected from counterfeiting and reverse-engineering. The electronic system includes one or more finite state machines (FSMs) describing behavior of at least a portion of the electronic system, and a reconfigurable module inserted in at least one of the FSMs. The reconfigurable module is configured when configuration bits are loaded in the reconfigurable module. The electronic system includes a non-volatile memory device storing the configuration data separately from the reconfigurable module. The configuration data may be the configuration bits themselves or other data used to generate the configuration bits.

### BRIEF DESCRIPTION OF THE DRAWINGS

The above and other aspects, features and other advantages will be more clearly understood from the following detailed description taken in conjunction with the accompanying drawings, in which:

FIG. 1 is a computing device suitable for practicing an exemplary embodiment;

FIG. 2 is a flow chart showing the steps for designing electronic systems in an exemplary embodiment;

FIG. 3 shows an exemplary embodiment where an original finite state machine (FSM) is embedded into a fake FSM;

FIG. 4 is an exemplary state transition graph of a one-hot FSM;

FIG. 5 is an exemplary logic implementing the transitions into a state of the FSM depicted in FIG. 4;

FIG. 6 is an exemplary logic implementing the transitions into a state of the FSM depicted in FIG. 4 and obfuscated by state replacement;

FIG. 7 is an exemplary logic implementing the transitions into a state of the FSM depicted in FIG. 4 and obfuscated by transition replacement;

FIG. 8 shows an exemplary embodiment using a configuration FSM for generating configuration data; and

FIG. 9 is an exemplary transition state graph of the configuration FSM depicted in FIG. 8.

### DETAILED DESCRIPTION

An exemplary embodiment provides an efficient method and apparatus for preventing electronic systems from counterfeiting and reverse-engineering. In the exemplary embodiment, an electronic system may be implemented on a chip. A system designer may design the control logic of the electronic system with one or more finite state machines (FSMs). The system designer may insert in at least one of the FSMs a reconfigurable module to obfuscate the FSM. The reconfigurable module can be configured differently depending on the configuration data, and only one of the configuration data is correct for the electronic system. Therefore, the exemplary embodiment can protect the electronic device from counterfeiting and reverse-engineering by securing the functionality of the FSM with the configuration data.

An exemplary embodiment may assign a unique key to the reconfigurable module so that the configuration data is encrypted with the key. Furthermore, the configuration data is separately stored in a secure memory device and loaded in the reconfigurable module when the electronic system is turned on. As such, the combination of the configuration data stored in a secure memory device and the reconfigurable module inserted in the FSM of the electronic system creates an efficient defense against counterfeiting and reverse-engineering.

### Design Tool

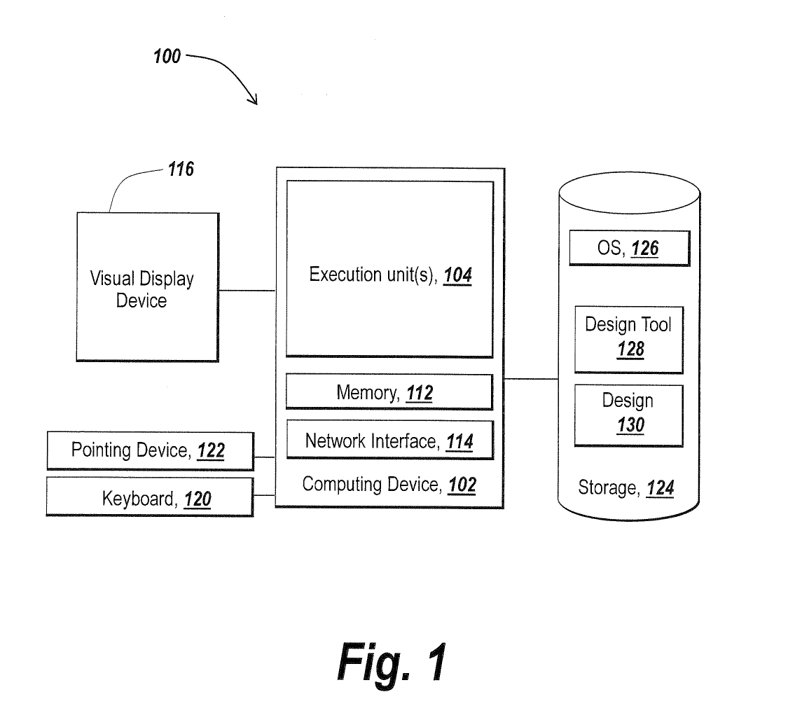

FIG. 1 is an exemplary computing device 100 suitable for practicing an exemplary embodiment. Computing device 102 may include execution unit 104, memory 112, network interface 114, I/O devices, such as keyboard 120, pointing device 122, and display device 116, and storage 124.

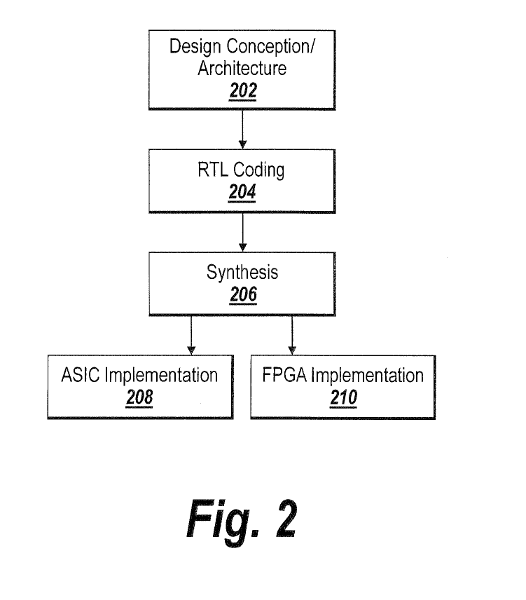

The storage device 124 may be, for example, a hard-drive, CD-ROM or DVD, for storing an operating system (OS) 126 and for storing application software programs, such as design tool 128. Design application or tool 128 may enable system designers (“users”) to design an electronic system, such as an integrated circuit (IC). Using design tool 128, the users can design an electronic system that is protected from counterfeiting and reverse-engineering. Design tool 128 may generate a design 130 of the electronic system in different levels. For example, the design 130 may describe the electronic system in computer readable code, such as hardware description language. The design 130 may also describe the electronic system in a netlist level. An exemplary design flow using design application or tool 128 will be described below with reference to FIG. 2.

FIG. 2 is a flow chart showing exemplary steps for designing electronic systems using design application or tool 128 depicted in FIG. 1. The designers or users may conceive of a design (step 202). This conception is generally abstract, and information at this stage may be input to design application or tool 128. The conception is converted into software code, such as hardware description language (step 204). In this step, the design intent is converted into software code that represents the electronic system at the clock-cycle by clock-cycle level.

The computer code is converted into a structural netlist including Boolean primitive functions (OR, NOR, XOR, AND, and others) interconnected by wires (step 206). Design application or tool 128 interprets the computer readable code and performs optimizations to convert the design as specified in the computer code into the structural netlist. This design is now timing-optimized, in that a system built in the way specified in the structural netlist will likely operate at the target design frequency. The structural netlist is used to implement the design through either the ASSP/ASIC (step 208) or FPGA (step 210).

### Finite State Machine

An exemplary embodiment may determine the operation of an electronic system by control logic. The electronic system may include control logic and data-path logic. The control logic may be implemented by finite state machines (FSMs) that direct communication protocols and the behavior of data-path logic.

An FSM is a behavior model sometimes used to design digital logic or computer program. An FSM has finite internal memory. An FSM includes a finite number of states, transitions between the states, and actions so that the operation of an FSM begins from one of the states, goes through transitions depending on input to different states and can end in any of the states available.

The exemplary embodiment protects the electronic system from counterfeiting and reverse-engineering by making the behavior of the FSMs partially reconfigurable. The reconfigurable portion of the FSMs is configured by configuration bits. The configuration bits are loaded when the electronic system is turned on. They may be stored in a secure memory device or may be generated based on other data stored in a secure memory device.

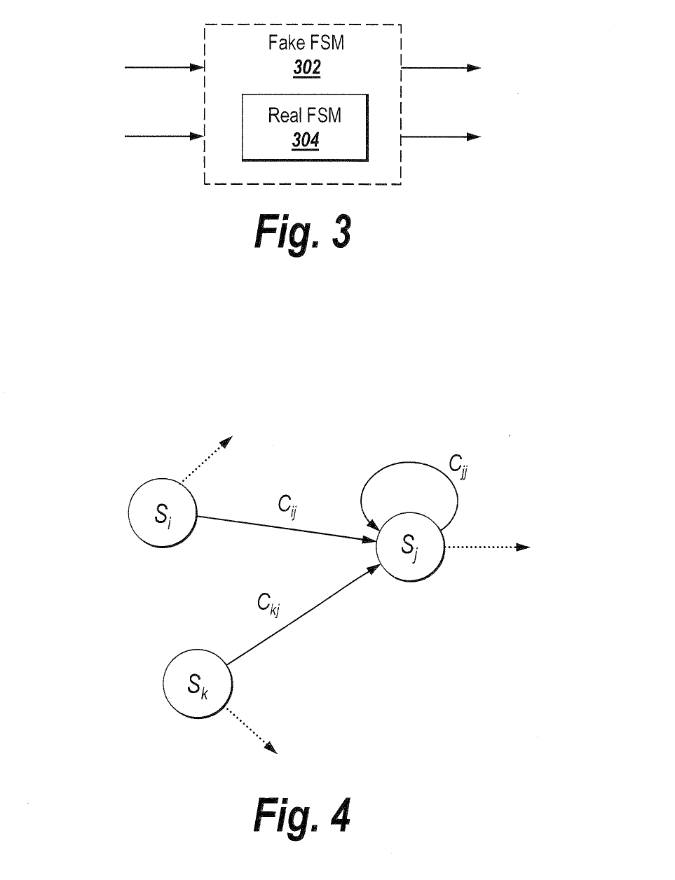

FIG. 3 shows an exemplary embodiment where one original FSM 304 is embedded into a fake FSMs 302. For example, the fake FSM may have n configuration bits and 2ⁿ configurations are possible. Only one of the 2ⁿ possible configurations creates original FSM 304, while all the other 2ⁿ−1 configurations create FSMs that preclude the normal operation of the electronic system. The silicon foundries and adversaries do not have the correct configuration, so that the design of the electronic system is protected from counterfeiting and reverse-engineering.

FIG. 4 is an exemplary state transition graph of a one-hot FSM. In a one-hot FSM, each state has a state flip-flop that is set when the FSM is in that particular state, while all other state flops are 0. Therefore, determining the current state is as simple as reading the state flip-flops. In the exemplary state transition graph, Sₓ is a state and C_{xy} denotes the condition causing the FSM to transition from Sₓ to S_{y}. For every state Sₓ there is one flip-flop, which is called Sₓ. Sₓ=1 denotes that Sₓ is the current state of the FSM.

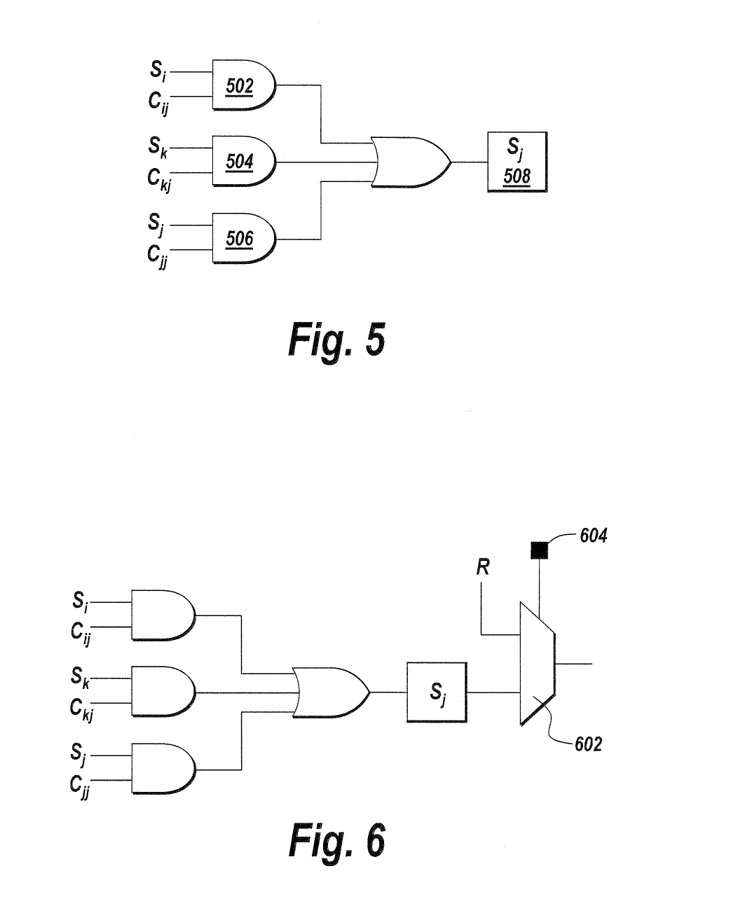

FIG. 5 illustrates the canonical, two-level logic that implements all the transitions into state Sⱼ of the one-hot FSM depicted in FIG. 4. AND gates 502, 504, 506 represent transitions into state Sⱼ. AND gate 502 implements the state transition from state Sᵢ into state Sⱼ under condition Cᵢⱼ. AND gate 504 implements the state transition from state Sₖ into state Sⱼ under condition Cₖⱼ. AND gate 506 implements a self-loop, where Cⱼⱼ represents the condition under which the FSM remains in state Sⱼ.

An exemplary embodiment constructs a fake FSM by modifying the design of the original FSM. The exemplary embodiment inserts in the original FSM a reconfigurable module that can be configured by configuration bits. The reconfigurable module may change states, state transitions, inputs, and outputs. The reconfigurable module may add new states and new inputs.

### State Replacement

FIG. 6 is an exemplary logic implementing the transitions into state Sⱼ of the one-hot FSM depicted in FIG. 4 and obfuscated by state replacement. In an exemplary embodiment, the state replacement technique may insert a reconfigurable module in the original FSM to substitute state Sⱼ of the original FSM with replacement state R. Replacement state R may be a state in the original FSM, a state in a different FSM, or a newly created fake state. The reconfigurable module may include multiplexer (MUX) 602 and configuration bit 604 connected to MUX 602 and the state replacement is controlled by the operation of MUX 602 and configuration bit 604. MUX 602 receives state Sⱼ and replacement state R and outputs one of state Sⱼ and replacement state R based on the configuration data in configuration bit 604.

In the exemplary embodiment, the state replacement modifies the original FSM by changing the transitions from state Sⱼ and the outputs depending on state Sⱼ. If replacement state R is a state from a different FSM not connected to the original FSM, the two FSMs become interconnected in the modified design. One of ordinary skill in the art will appreciate that one-hot encoding is an illustrative example and fake FSMs are not constrained to the one-hot encoding. Rather, the fake FSM concept may apply to other types of encoding, such as binary encoding.

A replacement MUX controlled by a configuration bit can be directly used to replace an FSM output signal without any state substitution. However, such a signal replacement may be more visible than a modification of the state transition graph of a FSM. The most useful modifications are those that cause the greatest number of changes in the behavior of the original FSM. The states to be replaced can be determined such that the replaced states affect the largest number of state transitions and outputs.

### Transition Replacement

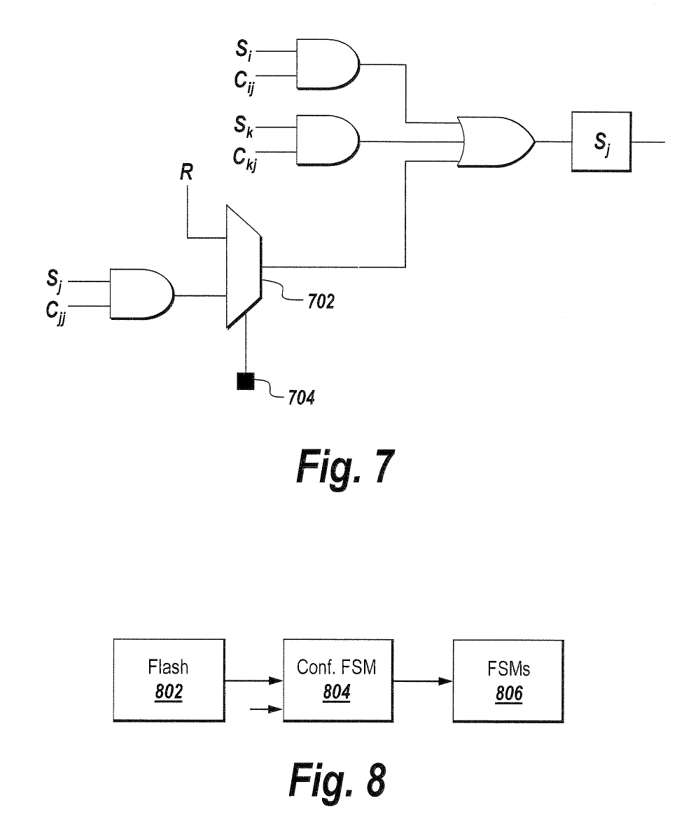

FIG. 7 is an exemplary logic implementing the transitions into state Sⱼ of the FSM depicted in FIG. 4 and obfuscated by transition replacement. In an exemplary embodiment, the transition replacement technique may insert a reconfigurable module in the original FSM to substitute a transition of the original FSM. In FIG. 7, the gate implementing the self-loop of state Sⱼ is replaced by replacement signal R. The reconfigurable module may include multiplexer (MUX) 702 and configuration bit 704 connected to MUX 202 and the transition replacement is controlled by MUX 702 and configuration bit 704. MUX 702 receives a transition from state Sⱼ and replacement signal R and outputs one of a transition from state Sⱼ and replacement signal R based on the value loaded in configuration bit 704.

Replacement signal R may be the output of a gate implementing a different transition in the original FSM or in a different FSM. Alternatively replacement signal R may be a fake, or an existing state in the original FSM or in a different FSM. When R is a state, the replacement introduces an unconditional transition from R to Sⱼ. If R=Sⱼ, then once the FSM enters Sⱼ, it remains locked in this state.

The resulting FSMs are significantly more complex than the original FSMs. All the FSMs that are separated in the original design may be linked into one FSM in the modified design. The state space may increase exponentially, since any configuration bit doubles the number of states. If the modified design has n configuration bits, the original design can be obtained by only one of the 2ⁿ possible configurations. Reverse-engineering of the device without knowing the configuration bits needed for its correct functional operation is useless since any other configuration generates a circuit whose behavior is very different from the normal operation. Using a large n (for example, n≧64) makes exhaustive analysis practically infeasible.

### Configuration Data

In an exemplary embodiment, the configuration bits for correct configuration of an electronic system are stored separate from the reconfigurable modules inserted into the FSMs. The configuration bits may be stored in a non-volatile memory device, such as a flash memory device. The configuration bits may be stored on the same chip where the electronic system is implemented. Alternatively, the configuration bits may be stored on a different chip than the electronic system and assembled in the same circuit board so that the configuration bits are loaded in the electronic system when the circuit is turned on.

The chip designer knows the correct configuration bits, and saves their correct values in a secure memory device. The configuration occurs automatically each time power is turned on. This feature prevents counterfeiting by overproduction since all the chips produced by the manufacturer are inoperable without the correct configuration data.

The chip designer may control the level of obfuscation. The first option is to have the n configuration bits stored in a secure memory. The level of obfuscation may differ depending on the number of configuration bits. The chip manufacturer may be given a non-functional configuration that is different from the correct configuration required for the normal operation of the chip. Manufacturing tests may not require the device to work in its full functional mode.

The second option is to have a configuration FSM 804 that receives its initial state from a non-volatile memory device 802 and generates configuration bits for obfuscated functional FSMs 806, as shown in FIG. 8. For certain initial states, configuration FSM 804 generates correct configuration values required for the normal operation of obfuscated functional FSMs 806, while starting from other initial states leads to non-functional configurations. None of the manufactured chips work correctly until the configuration data is generated from a correct initial state. In this scheme, the configuration bits are not stored in a memory device.

In addition to the configuration bits, configuration FSM 804 can also provide obfuscated functional FSMs 806 with fake inputs and/or fake states for obfuscation. For example, one of the state bits that is not a configuration bit in the configuration FSM can be used to supply the replacement state or signal R in FIG. 6 or 7.

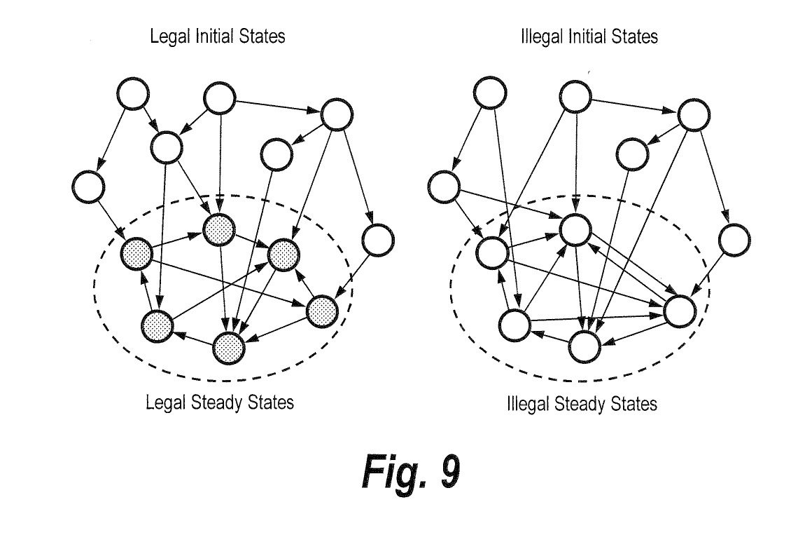

FIG. 9 shows an exemplary operation of configuration FSM 804 depicted in FIG. 8. The states are divided into two disjoint subsets called “legal” and “illegal.” Starting from any legal initial state, configuration FSM 804 enters one of the legal steady states within at most k clock cycles. After that, it remains in the strongly connected group of legal steady states. The correct configuration bits are common among all the states in this group, so they do not change even if other state bits of the configuration FSM change. Several paths may exist from an initial state to the steady states. Also, several paths may exist from one steady state to other steady states. The path taken depends on the inputs of the configuration FSM, which are arbitrary functional signals from the circuit. The actual paths traversed in operation do not really matter, since any path from an initial state leads to a steady state within at most k cycles, and any path from a steady state leads only to another steady state. The illegal states have a similar behavior, but the configuration bits they provide are always different from the correct ones, so the behavior of the obfuscated FSMs is guaranteed to be incorrect when the initial state is illegal.

The number of legal initial states is much smaller than the number of illegal initial states to reduce the probability of an adversary finding a legal initial state by experimenting with different initial states. The chance of identifying a legal initial state may be further reduced because realizing that the operation of the chip is incorrect may take a long time, and each illegal configuration creates a different incorrect behavior. Although the adversary may have a structural model of the electronic system, the operation of the configuration FSM is difficult to understand since it depends on an initial state that is invisible (hidden in a secure memory device) and on inputs who are actually “don't care”.

Unlike the first option, where the configuration bits are constant after loading from the secure memory, in this scheme the configuration bits are changing during the first k cycles.

An additional degree of obfuscation can be obtained by making the behavior of the chip pseudo-deterministic. The normal operation can start any time after the configuration bits have reached their correct values, so we can start after the first k+r cycles, where r is a random parameter that varies from run to run (for example, r can be produced by a random number generator). Reverse engineering relying on analyzing the chip behavior in different runs becomes more complicated if signal values in different runs are difficult to correlate since the legal operation has a different starting point in each run.

The different legal initial states can serve as chip identifiers in an exemplary embodiment. Since there may be several legal initial states, it is possible to load each chip with a different legal initial state. Therefore, the different legal initial state loaded in each chip can serve as the identifier of the chip. With this feature, the exemplary embodiment can create unique identifiers to keep track of the legally manufactured chips. An adversary does not have knowledge of the legal initial states.

In an exemplary embodiment, the degree of obfuscation can be increased by making the configuration FSM partially reconfigurable as well, using the same techniques as those used for the functional FSMs. The configuration data of the configuration FSM may be stored in a non-volatile memory device along with the initial state. The degree of obfuscation can also be increased by encrypting the configuration data or the initial state stored in a non-volatile memory device. The configuration data or the initial state may be encrypted with a key assigned to the chip. The encryption key may be derived from a Physically Unclonable Function (PUF) technique. The key may be generated on demand and does not need to be stored inside the chip.

The degree of obfuscation can be further increased by replacing selected data-path blocks with reconfigurable hardware. The reconfigurable hardware is configured by the same configuration mechanism described above. The techniques for replacing selected data-path logic with reconfigurable hardware are described in more detail in co-pending application (Attorney Docket No. DAW-020) filed on Oct. 13, 2010 and entitled “PROTECTING ELECTRONIC SYSTEMS FROM UNAUTHORIZED ACCESS AND HARDWARE PIRACY.” The content of the aforementioned application is incorporated by reference.

Exemplary embodiments are described above. It is, however, expressly noted that these exemplary embodiments are not limiting, but rather the intention is that additions and modifications to what is expressly described herein also are included within the scope of the present implementation. Moreover, it is to be understood that the features of the various embodiments described herein are not mutually exclusive and can exist in various combinations and permutations, even if such combinations or permutations are not made express herein, without departing from the spirit and scope of the present implementation.

Since certain changes may be made without departing from the scope of the present implementation, it is intended that all matter contained in the above description or shown in the accompanying drawings be interpreted as illustrative and not in a literal sense. Practitioners of the art will realize that the sequence of steps and architectures depicted in the figures may be altered without departing from the scope of the present implementation and that the illustrations contained herein are singular examples of a multitude of possible depictions of the present implementation.

What is claimed as new and desired to be protected by Letters Patent of the United States is:

1. A method of designing an electronic system to protect from counterfeiting and reverse-engineering, the method comprising:
describing a control part of the system by finite state machines (FSMs);
inserting a reconfigurable module in at least one FSM, the reconfigurable module being configured by configuration bits; and
saving the values of the configuration bits separately from the reconfigurable module.

2. The method of claim 1, wherein the electronic system comprises an integrated circuit (IC).

3. The method of claim 1, wherein the reconfigurable module is inserted to change one or more states in the FSM.

4. The method of claim 1, wherein the reconfigurable module is inserted to change one or more state transitions in the FSM.

5. The method of claim 1, wherein the reconfigurable module is inserted to change outputs in the FSM.

6. The method of claim 1, wherein the reconfigurable module is inserted to change or add one or more inputs in the FSM.

7. The method of claim 1, wherein the configuration data is saved in encrypted form and the encrypted configuration data is decrypted before being loaded in the reconfigurable module.

8. The method of claim 1, wherein the configuration data is stored in a non-volatile memory and the non-volatile memory is implemented on the same chip as the electronic system.

9. The method of claim 1, wherein the configuration bits are generated by a second FSM that received initial state stored in a non-volatile memory.

10. The method of claim 9, wherein the second FSM is configurable by a second configuration data.

11. The method of claim 1, further comprising:
replacing a portion of the electronic system with a second reconfigurable module, the second reconfigurable module being configured by a second configuration data; and
saving the second configuration data separately from the second reconfigurable module,
wherein the second reconfigurable module is configured to correspond to the portion of the electronic system when the second configuration data is loaded in the second reconfigurable module.

12. An electronic system protected from counterfeiting and reverse-engineering, the system comprising:
a finite state machine (FSM) describing behavior of at least a portion of the electronic system;
a reconfigurable module inserted in the FSM, wherein the reconfigurable module is configured when configuration data is loaded in the reconfigurable module; and
a non-volatile memory device storing the configuration data separately from the reconfigurable module.

13. The electronic system of claim 12, wherein the electronic system comprises an integrated circuit (IC).

14. The electronic system of claim 12, wherein the reconfigurable module comprises a Programmable Logic Devices (PLD).

15. The electronic system of claim 12, further comprising:
a multiplexer connected to a first state in the FSM, the multiplexer receiving a second state; and
a configuration bit connected to the multiplexer, the configuration bit configuring the multiplexer so that the multiplexer outputs one of the first state and the second state.

16. The electronic system of claim 16, further comprising:
a multiplexer connected to a gate representing a first transition in the FSM, the multiplexer receiving a replacement value; and
a configuration bit connected to the multiplexer, the configuration bit configuring the multiplexer so that the multiplexer outputs one of the replacement value and an output of the gate.

17. The electronic system of claim 12, further comprising a second FSM that receives initial states stored in a non-volatile memory and generates the configuration bits.

18. The electronic system of claim 17, wherein the second FSM is configurable by a second configuration data stored in a non-volatile memory.
